(19) United States
(12) Patent Application Publication
(10) Pub. No.: US 2013/0199331 A1
(43) Pub. Date: Aug. 8, 2013

(54) MACHINE ELEMENT

(71) Applicant: SCHAEFFLER TECHNOLOGIES AG & CO. KG, Herzogenaurach (DE)

(72) Inventors: Frank Himsel, Obermichelbach (DE); Holger Patzold, Burgebrach (DE)

(73) Assignee: SCHAEFFLER TECHNOLOGIES AG & CO. KG, Herzogenaurach (DE)

(21) Appl. No.: 13/792,740

(22) Filed: Mar. 11, 2013

Related U.S. Application Data
(63) Continuation-in-part of application No. PCT/EP2012/052989, filed on Feb. 22, 2012.

(30) Foreign Application Priority Data
May 24, 2011 (DE) 102011076410.0

(51) Int. Cl. C23C 16/56; F16H 53/06

(52) U.S. Cl. CPC C23C 16/56; F16H 53/06
USPC 74/569; 118/724; 118/715

(57) ABSTRACT

A machine element that has a surface with an isotropic structure that is formed by a coating, and is subjected to rolling or sliding stress. The coating on the surface is by a PVD process, and the surface brushed with a tool while supplying a cooling lubricant during the brushing such that no chemical reaction takes place between the tool and the machine element.

### INCORPORATION BY REFERENCE

The following documents are incorporated herein by reference as if fully set forth: German Patent Application No. 102011076410.0, filed May 24, 2011; and International Application No. PCT/EP2012/052989, filed Feb. 22, 2012.

### FIELD OF THE INVENTION

The invention relates to a machine element exposed to a rolling or sliding load, in particular a valve drive element of an internal combustion engine or a rolling bearing component.

### BACKGROUND

DE 10 2007 054 181 A1 discloses a bucket tappet provided with a corrosion-resistant coating. The coating in this case has a multi-layer structure and comprises amorphous carbon containing hydrogen.

A process for machining a coating made of hard carbon is known, for example, from DE 10 2006 010 916 A1. In this case, bristle-shaped or plate-shaped elements are used for smoothing the surface.

Arc processes suitable for coating surfaces are disclosed, for example, in DE 10 2007 058 356 A1.

Various wear-resistant coatings comprising CrNₓ phases or carbon-containing functional layers (Me-C:H, a-C:H, a-C:H:a, ta-C) are known, for example, from DE 10 2004 043 550 A1.

### SUMMARY

The invention is based on the object of further developing a process for coating a machine element, in particular a cam follower and/or rolling bearing part, over the cited prior art, in particular with respect to the wear and friction properties.

This object is achieved by a process having one or more of the features according to the invention. Proceeding from DE 10 2006 010 916 A1, as mentioned above, the invention is based on the recognition that the brushing described therein leads to very high temperatures, which may result in a chemical reaction in the coating. In particular, according to the recognition of the invention, the carbon coating is partially converted into graphite already above 700° C. by the brushing. This considerably impairs the mechanical strength. During brushing with ferrous metals, iron carbides may additionally form, and these likewise reduce the strength on account of their brittleness.

Precisely conversely to that described in the prior art, the affinity of the brush material for coating should precisely not set in as a result of the invention. Instead of a chemical smoothing action, solely mechanical removal of material should lead to the smoothing in the invention. Surprisingly, this can be achieved by supplying cooling lubricant during the brushing. This firstly keeps the temperature low enough to avoid a chemical reaction. Secondly, despite the lubricating effect, a sufficiently high abrasion can surprisingly be achieved for the smoothing, and therefore in particular droplets are removed to an adequate extent.

The coating is preferably in the form of a DLC (Diamond-Like Carbon) coating. The cooling lubricant may be, for example, both an emulsion on an aqueous basis and also a synthetic oil or an oil based on mineral oil.

The coating is preferably applied by the PVD process. This applies in particular to hydrogen-free carbon layers and crystalline hard material layers such as CrN. Amorphous hydrocarbon layers are, by contrast, preferably applied by the PACVD process.

After the coating has been applied, mechanical remachining is effected by brushing.

The still uncoated, isotropic surface of the machine element preferably has a roughness of 0.003 to 0.01 μm Ra. The application of the coating brings about a build up of roughness to typically 0.05 to 0.08 μm Ra. Finally, in an advantageous configuration, a roughness of 0.01 to 0.025 μm Ra is achieved by the mechanical remachining of the coating of the machine element. The low surface roughness of the machine element corresponds to a high bearing fraction of the mechanically loaded surface both in the case of rolling contact and in the case of sliding contact.

If droplets form in the coating as a result of the coating process, they are removed preferably partially, but not completely, by the mechanical remachining. In a small number and with a low markedness, droplets can assist the running-in of the coated machine element, in particular valve drive element, in relation to the opposing body, for instance in relation to a cam or in relation to a rolling body.

The tool used for mechanically remachining the coating may be a brushing tool populated with diamond fill, but brushes made of metal or even of plastic are also feasible. In the case of metal brushes, in particular with an iron content, the supply of cooling lubricant prevents a chemical reaction. Brushing tools containing CBN (cubic boron nitride), corundum or carbide can also be used. If brushes made of pure plastic are used, the lubrication could possibly be reduced or even be dispensed with entirely, since here chemical reactions with the coating are less critical than when metal-containing brushing tools are used. Graphitization (conversion of the tetragonal sp3 bonds into hexagonal sp2 bonds) of the DLC layer, in particular, would be visible as a chemical reaction. The supply of coolant also affords protection for the brushing tool. The tool for mechanical remachining can preferably be in the form of a filament which is populated or infiltrated by particles and which makes it possible for the coated surface to be brushed uniformly. An adequate supply of cooling lubricant during the brushing in this case ensures that material is removed, in particular droplets are partially removed, exclusively by mechanical means, with no chemical reaction taking place between the tool and the workpiece and graphitization of the DLC layer being reduced or avoided entirely on account of the low temperature.

Possible uses of the coating according to the invention are, for example, bucket tappets and finger or rocker levers in piston engines, but also pump tappets, toothed wheels or rolling bearing components, in particular bearing rings and rolling bodies, for example balls, needles, cylindrical rollers or conical rollers. Steel is used with preference as the base material of the machine element to be coated; the coating may, however, also be applied to a workpiece made of light metal, for example.

### BRIEF DESCRIPTION OF THE DRAWINGS

An exemplary embodiment of the invention will be explained in more detail hereinbelow with reference to a drawing, in which:

FIG. 1 shows a bucket tappet in a perspective view, and

FIG. 2 shows the bucket tappet shown in FIG. 1 in a sectional illustration.

### DETAILED DESCRIPTION OF THE PREFERRED EMBODIMENTS

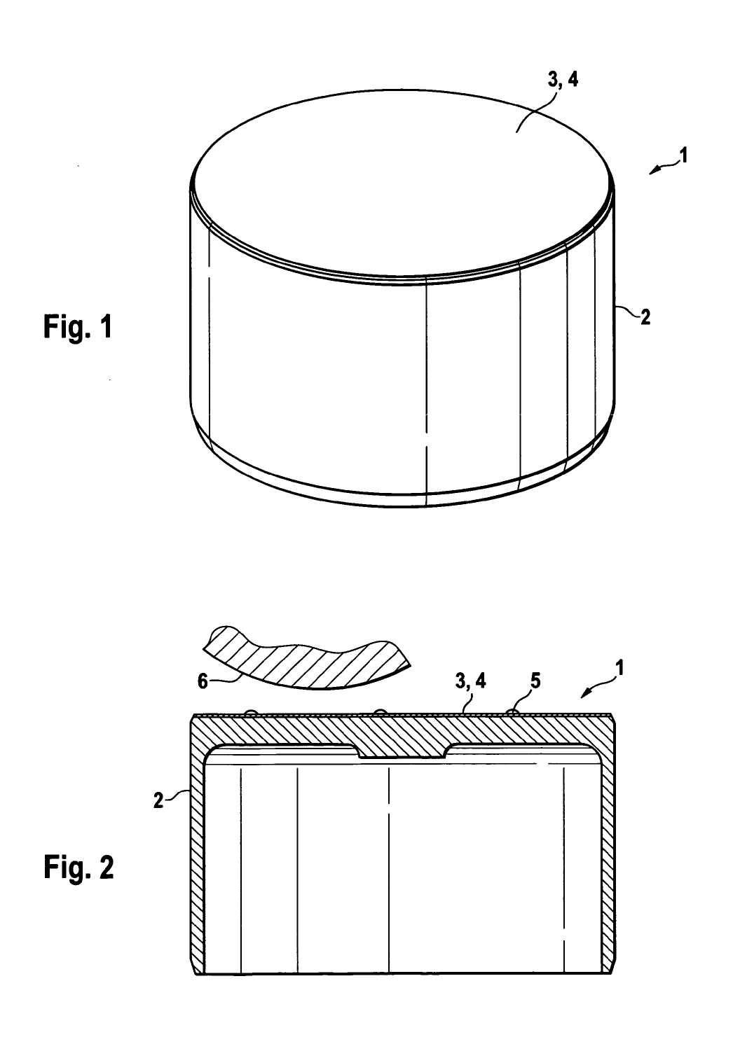

A machine element denoted by the reference sign 1 in FIGS. 1 and 2, i.e. a bucket tappet, has a cylindrical lateral surface 2 and also a surface 3 in the form of a circular disk, which forms a sliding surface intended to interact with a cam (not shown). With respect to the fundamental function of the bucket tappet 1, reference is made to the prior art cited in the introduction.

The surface 3 is formed by a coating 4, which is applied by the PVD process and has an isotropic structure as a result of suitable pretreatment. In terms of its chemical composition and its layer structure, the coating 4 corresponds, for example, to a coating known from documents DE 10 2007 054 181 A1, DE 10 2006 010 916 A1, DE 10 2007 058 356 A1 or DE 10 2004 043 550 A1. In FIG. 2, a plurality of droplets 5 are indicated in exaggerated form in the form of particles protruding in the coating 4.

The entire coating 4, including the droplets 5 which may form as a result of the process, is produced by the PVD (Physical Vapor Deposition) process and is referred to as a DLC (Diamond-Like Carbon) coating. By way of example, the coating 4 is a hydrogen-free carbon layer with preferably tetragonal bonds (ta-C layer). Similarly, the coating 4 may be in the form of an amorphous hydrocarbon layer (a-C or a-C:H), which may have a single-layer or multi-layer structure and be doped with metals or nonmetals, the layer in this case preferably being produced by the PACVD (Physical Assisted Chemical Vapor Deposition) process. Nitridic hard material layers such as chromium nitride or copper-molybdenum nitride are also feasible as the coating 4 or components of the coating 4, in particular in the case of a multi-layer structure.

Just before the coating 4 is applied, the surface 3 of the bucket tappet 1 to be coated is prepared for the coating process by polishing and/or lapping processes in such a manner that virtually no directional mechanical machining traces, for instance grinding traces from machining which possibly took place beforehand, are visible any more. The coated surface 3 finally is remachined using a brushing tool 6, which has, for example, a planetary gear, is shown only in sections in FIG. 2 and is populated with diamond particles. In principle, the bucket tappet 1 and/or the brushing tool 6 can be driven during the mechanical remachining, i.e. during the brushing. The brushing tool 6 is preferably temperature-stable up to at least 350° C.

The brushing operation is in any case configured in such a manner that each portion of the surface 3 to be machined is machined uniformly, in particular without preference for any specific direction, both in terms of the machining intensity and the relative movement between the workpiece, i.e. the bucket tappet 1, and the brushing tool 6, such that ultimately an isotropic surface structure optimized in terms of wear and friction is formed. The droplets 5 are in this respect removed uniformly and nondirectionally, but as a whole in a reproducible manner. In the case of a coating process which generates no droplets in the coating 4, it may be sufficient—without the need for mechanical remachining—if an isotropic structure is present in the still uncoated surface 3 of the bucket tappet 1.

In the case of a metal-containing brushing tool 6 and also in the case of a plastics-based brushing tool 6, a cooling lubricant is added, and keeps the temperature of the coating 4 sufficiently low, in particular below 700° C. This keeps chemical reactions in the coating 4, for instance phase transformation into graphite or the formation of metal carbides, low, and therefore the mechanical load-bearing capacity of the coating 4 is not appreciably reduced.

In the case of the plastic brushing tool 6, it is preferably made from a plastic selected from the group consisting of at least one of: thermoplastics, polyamides, nylon (which is a polyamide), aramid (an aromatic polyamide), and glass fibers, in pure form and also as an incorporated filler. The plastic brushing tool 6 can be used without an incorporated abrasive media.

### LIST OF REFERENCE SIGNS

1 Machine element, bucket tappet

2 Lateral surface

3 Surface, sliding surface

4 Coating

5 Droplet

6 Brushing tool

1. A process for machining a surface of a machine element exposed to a rolling or sliding load, comprising applying a coating the surface by a PVD process, and brushing the surface with a tool while supplying a cooling lubricant during the brushing such that no chemical reaction takes place between the tool and the machine element.

2. The process as claimed in claim 1, wherein the coating is a DLC layer, and a machining temperature is kept so low by the supply of the cooling lubricant that the DLC layer is not graphitized.

3. The process as claimed in claim 1, wherein the surface is machined in such a manner that droplets present in the coating are at least partially removed.

4. The process as claimed in claim 1, wherein the surface is machined using a brushing tool as the tool that is populated with diamond, CBN, corundum or carbide.

5. A machine element having a coating applied according to claim 1, wherein the machine element comprises a cam follower which is one of a bucket tappet, a finger lever, or a rocker arm

6. A process for machining a surface of a machine element exposed to a rolling or sliding load, comprising applying a DLC coating to the surface by a PVD process, and brushing the surface wherein a material used for brushing is a plastic without an incorporated abrasive media.

7. The process as claimed in claim 6, wherein the plastic is selected from the group consisting of at least one of:
thermoplastics,
polyamides,
nylon,
aramid, and
glass fibers, in pure form and also as an incorporated filler.
